(19) United States
(12) Patent Application Publication
(10) Pub. No.: US 2017/0301901 A1
(43) Pub. Date: Oct. 19, 2017

(54) Systems, Devices, and/or Methods for Managing Batteries

(71) Applicant: Directed Vapor Technologies International, Inc., Charlottesville, VA (US)

(72) Inventors: Derek Hass, Charlottesville, VA (US); Daniel Lobo, Charlottesville, VA (US)

(73) Assignee: Directed Vapor Technologies International, Inc., Charlottesville, VA (US)

(21) Appl. No.: 15/489,553

(22) Filed: Apr. 17, 2017

Related U.S. Application Data
(60) Provisional application No. 62/324,261, filed on Apr. 18, 2016.

(51) Int. Cl. H01M 2/16; H01M 10/0525; H01M 4/38; H01M 2/14; C23C 16/50; C23C 16/448; C23C 16/40; C23C 16/30; H01M 12/08; C23C 8/80

(52) U.S. Cl. CPC H01M 2/166; H01M 12/08; H01M 10/0525; H01M 4/382; H01M 2/1686; C23C 8/80; C23C 16/50; C23C 16/4481; C23C 16/40; C23C 16/308; H01M 2/145

(57) ABSTRACT

Certain exemplary embodiments can provide a system, which can comprise an ultra-thin polymer ceramic composite separator. The ultra-thin polymer ceramic composite separator can comprise Li-ion conducting ceramic material. The ceramic composite separator has a columnar grained microstructure. The ultra-thin polymer ceramic composite separator can comprise a single or bi-layer combination of LiPON, LATP, garnets, lithium sulfides, or Li₁₊₂ₓZr_{2-z}Ca(PO₄)₃.

### CROSS-REFERENCES TO RELATED APPLICATIONS

This application claims priority to, and incorporates by reference herein in its entirety, pending U.S. Provisional Patent Application Ser. No. 62/324,261 (Attorney Docket No. 1099-04), filed Apr. 18, 2016.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. A wide variety of potential practical and useful embodiments will be more readily understood through the following detailed description of certain exemplary embodiments, with reference to the accompanying exemplary drawings in which:

FIG. 1 is executed in color. FIG. 1 shows A) Bi-layer LiPON/LATP deposition process. B) UTCPP Separator in transportable form and C) in final form;

FIG. 2 is a table;

FIG. 3 is a schematic representation of a system 3000; and

FIG. 4 is a flowchart of an exemplary embodiment of a method 4000.

### DETAILED DESCRIPTION

Certain exemplary embodiments can provide a system, which can comprise an ultra-thin polymer ceramic composite separator. The ultra-thin polymer ceramic composite separator can comprise Li-ion conducting ceramic material. The ceramic composite separator has a columnar grained microstructure. The ultra-thin polymer ceramic composite separator can comprise a single or bi-layer combination of LiPON, LATP, garnets, lithium sulfides, or Li₁₊₂ₓZr_{2-z}Ca(PO₄)₃.

The use of metallic lithium anodes is desired for advanced Li-based batteries (Li-ion, Li—S, Li-Air) to enable higher energy density and specific capacity. Unfortunately, when utilizing Li metal anodes, lithium dendrite growth during recharging can result in extreme roughening of the lithium surface, which can short circuit the battery cell. Mechanical suppression of the dendrite formation through the use of high shear modulus, Li-ion conducting materials is a promising approach to avoid the roughening issue and enable lithium metal anodes as Li-ion conducting ceramics have been developed with conductivities approaching that of liquid electrolytes. However, poor mechanical properties of the Li-ion conducting ceramics can be a significant challenge when manufacturing thin layers due to their poor toughness and sensitivity to defects. This has led to the use of polymer-ceramic composite separators having enhanced mechanical performance. Certain exemplary embodiments manufacture ultra-thin polymer ceramic composite (“UTPCC”) separators having a low ionic area-specific resistance, suitable mechanical properties and good compatibility in contact with lithium metal. Certain exemplary embodiments provide the manufacture of these separators in a cost effective manner via the use of a high rate, gas-jet assisted vapor deposition process that operates in a soft vacuum (approximately 10 Pa) to enable continuous roll-to-roll manufacturing onto flexible substrates. Using this manufacturing technique, UTPCC separators having thicknesses less than approximately 20 micrometers can be created.

Certain exemplary embodiments provide for a substantially continuous manufacture of UTPCC separator material meeting the specifications to allow the use of Li metal negative electrodes in multiple battery platforms (i.e. Li-ion, Li—S, Li-Air). The separators can comprise a bi-layer of high modulus, Li-ion conducting ceramic materials (e.g., a bi-layer comprising LiPON and LATP) having a columnar grained microstructure. A non-lithium ion conducting polymer (e.g., cyclo-olefin) can be infiltrated into the columnar pores to result in a polymer-ceramic composite membrane. The manufacture of these separators can utilize a relatively high rate, gas-jet assisted vapor deposition process that operates in a soft vacuum (approximately 10 Pa) to enable substantially continuous roll-to-roll manufacturing onto flexible substrates using a unique atmosphere to vacuum (“ATV”) technology.

Certain exemplary embodiments provide for safe, stable batteries having high energy and power density, long cycle lives and large operational temperature ranges are required in multiple applications. Li-based batteries can provide increased energy density over other batteries. Advanced manufacturing techniques can be utilized to develop Li-based batteries that are affordable to manufacture, long lived, safe, and deliver the high energy density values predicted theoretically. One area that has the potential to significantly enhance the performance of Li-based batteries (Li-ion, Li—S, Li-Air) is the use of metallic lithium anodes due to its ability to enable higher energy density and specific capacity. Unfortunately, lithium dendrite growth during recharging can result in extreme roughening of the lithium surface that can short circuit the battery cell. Mechanical suppression of the dendrite formation through the use of high shear modulus materials is a promising approach to avoid the roughening issue and enable lithium metal anodes. The suppression of dendrite formation can be achieved using materials having a shear modulus approximately twice that of Li metal. This generally excludes the use of organic Li-ion conducting membranes and requires ceramic or glass materials with higher shear moduli. The development of Li-ion conducting ceramics and glasses with conductivities approaching that of liquid electrolytes have made solid Li-ion conducting materials a viable approach for dendrite suppression. However, the manufacture of Li-ion conducting separators based on such materials can be limited by several factors:
the higher than desired ionic area-specific resistance (“ASR”) of these components;
the electro/chemical stability of these materials when in contact with Li metal and air; and/or
relatively poor mechanical properties of the thin ceramic/glass separators (i.e., low toughness).

The high ASR of current separator materials is a function of the higher than desired thickness (approximately 100 to approximately 250 microns) and the presence of high impedance grain boundaries and/or particle-to-particle interfacial resistances that are the result of convention powder based manufacturing approaches (i.e. powder compaction and sintering; tape casting). These issues resulted in a motivation to create very thin separators (less than approximately 20 microns) with limited grain boundary and interfacial resistance (i.e., substantially single crystals). The poor mechanical properties of the Li-ion conducting ceramics is a significant challenge when manufacturing thin layers due to their poor toughness and sensitivity to defects. This has led to the use of polymer-ceramic composite separators. For example, composite separators using a single layer of particles can be embedded in a polymer matrix. The approach uses a non Li-ion conducting polymer (e.g., cyclo-olefin) and approximately 100 micron diameter particles of an ion-conducting ceramic (e.g., Li_{1.6}Al_{0.5}Ti_{0.95}Ta_{0.5}(PO₄)₃ (LATTP)) to create durable, ion conducting layers. The non Li-ion conducting, organic matrix resists Li dendrite formation despite its relatively low shear modulus. The ASR of this material is, however, limited by the thickness, grain boundary resistance within the particles and the relatively low volume fraction of the LATTP in the composite. The LATTP is also not stable in direct contact with Li metal. Certain exemplary embodiments can utilize this basic composite concept while providing disruptive advances in performance that overcome these current drawbacks.

In certain exemplary embodiments, UTPCC separators can be created from the vapor phase using a high rate, high throughput physical vapor deposition approach that uniquely operates in a soft vacuum to allow gas jet assisted deposition and substantially continuous ATV processing. The gas jet assisted deposition allows for an enhanced deposition efficiency (and therefore very high deposition rates) and the utilization of a three dimensional coating zone (due to the non-line-of-sight coating capability of the process) for ultra-high coating throughout. The ATV technology allows substantially continuous roll-to-roll manufacturing.

Using this manufacturing technique, a bi-layered ceramic material (LiPON/LATP) having a columnar microstructure can be created. Where LiPON is lithium phosphorous oxy-nitride and LATP is Li₁₊ₓAlₓTi₂₋ₓP₃O₁₂. The columnar structure limits grain boundary resistance by aligning the boundaries in the direction of Li-ion transport and maximizing the volume fraction of the Li-ion conducting material. The bi-layer structure enables direct contact of the separator to Li metal. Infiltration of a non Li-ion conducting polymer into the columnar pores completes the composite structure. The proposed product utilizes several key innovations to create a disruptive product for the marketplace. These include:
1) Soft vacuum physical vapor deposition: Allowing substantially continuous atmosphere-to-vacuum roll-to-roll processing and non-line-of-sight physical vapor deposition.
2) High rate deposition of ceramic layers with columnar microstructures over large areas: greater than approximately 10 microns/min over large areas (greater than approximately one m²) appear feasible using moderately sized, affordable coaters.
3) 3D coating zone during physical vapor deposition: Enabled by non-line of sight (“NLOS”) coating capability.
4) Porosity tailoring: Microstructures having grains elongated in the desired Li-ion diffusion direction demonstrated for zirconia structures, which can reduce grain boundary resistance.
5) Bi-layer separators: for enhanced Li metal compatibility.

The innovations of exemplary embodiments provide an opportunity to affordably create very thin (approximately 5 to approximately 20 microns) composite separators (ceramic/polymer) having microstructures and architectures substantially optimized for Li-ion transport and electro-chemical stability using roll-to-roll processing. The anticipated metrics of the resulting separators are disclosed herein.

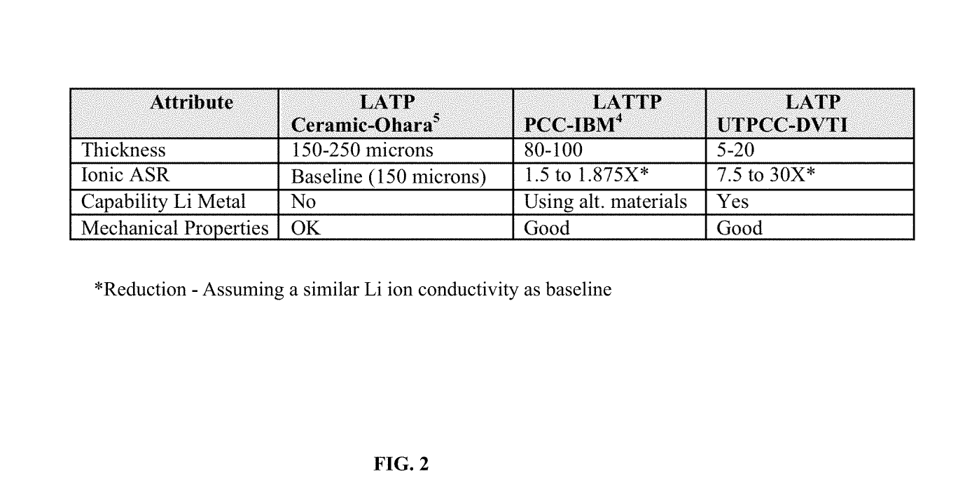

FIG. 2 is a table, which documents properties of an exemplary embodiment compared to two other materials.

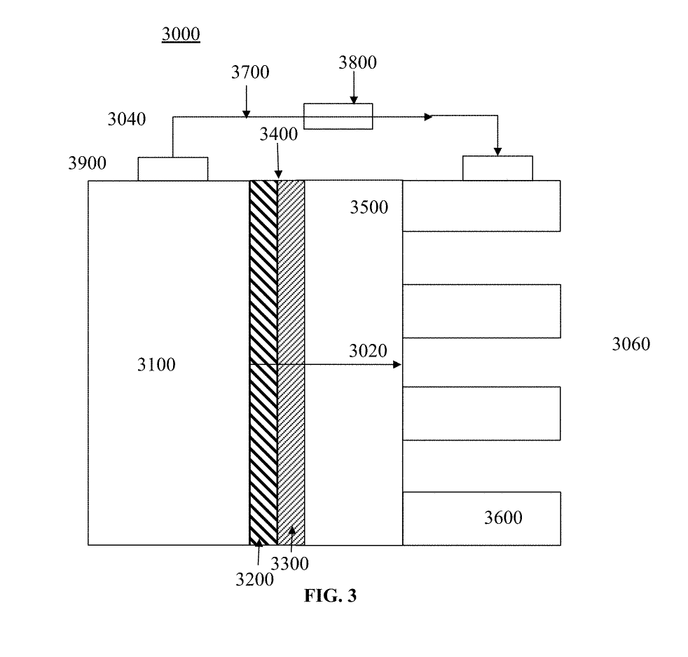

Certain exemplary embodiments provide a bi-layer ceramic comprising an initial LiPON layer (e.g., first bi-layer 3200 of FIG. 3) followed by an LATP layer (e.g., second bi-layer 3300 of FIG. 3). LiPON can be chosen based on its known compatibility with Li metal. This layer can be thin as its Li-ion conductivity is several orders of magnitude lower than LATP. The LATP layer can be chosen for the majority of the bi-layer due to its very high bulk Li-ion conductivity, good air stability and suitability for high rate evaporation. Li garnets and Li sulfide materials can also be considered. Li sulfides can also be considered for vapor deposition. Both single and bi-layer combinations of LiPON, LATP, garnets (examples include Li₇La₃Zr₂O₁₂) and Li sulfides (examples include Li₁₀GeP₂S₁₂) may be considered for use in the separator.

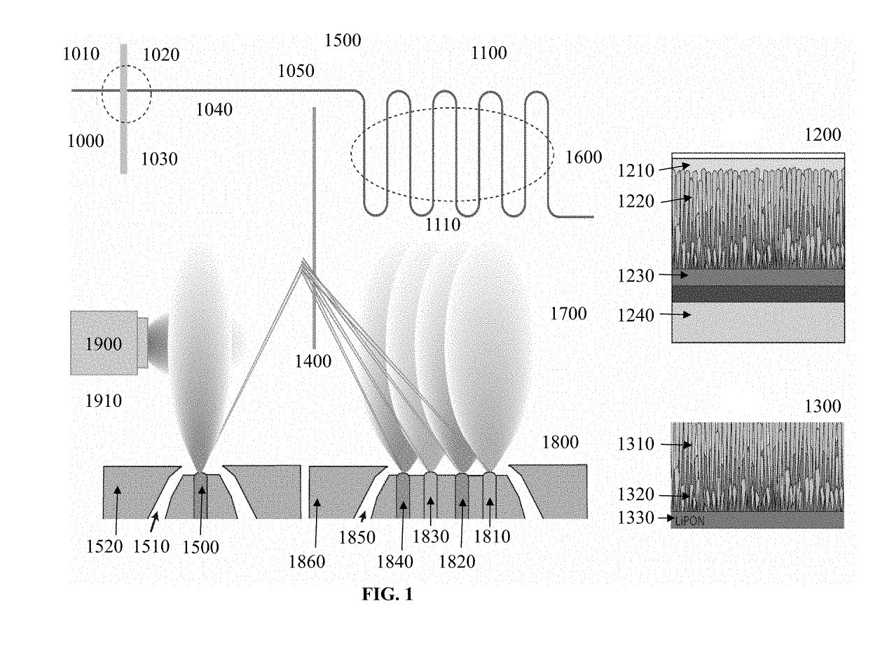

The manufacture of the separator can utilize a production scale Directed Vapor Deposition (“DVD”) coater. The DVD technology can utilize a supersonic gas jet to direct and transport an electron beam evaporated vapor cloud onto a component. Typical operating pressures are in the range of approximately 1 to approximately 50 Pa, which can utilize fast and inexpensive mechanical pumping such that chamber pump down times are short. In this processing regime, collisions between the vapor atoms and the gas jet create a mechanism for controlling vapor transport. This enables high rate deposition (by combining high evaporation rates with high deposition efficiency) and NLOS deposition that enables 3D utilization of the coating zone to increase the surface area of substrate that can be coated in a given time. Multi-source co-evaporation approaches can be utilized that allow the DVD coating zone to be scaled from small area, tightly focused cylindrical fluxes to large area rectangular fluxes. When such fluxes are used with 3D utilization (due to NLOS capabilities), the coating zone can easily exceed approximately one (1) square meter using moderately sized, relatively inexpensive coating equipment. Importantly, the soft vacuum used in the process enables ATV processing for substantially continuous roll-to-roll manufacturing. A production scale, roll-to-roll, continuous fiber/wire/tape handling system has been built that has been demonstrated for the application of functional coatings onto long lengths of continuous substrates (greater than approximately 2000 feet). Production scale DVD equipment can be used to manufacture UTPCC separators. This can comprise first depositing NaCl onto a metal foil. This can be followed by an in-situ deposition of a LiPON/LATP bi-layer, as shown in FIG. 1. The LiPON can be made by evaporating a LiPO₄ source in a plasma enhanced, nitrogen rich environment. The co-evaporation of LiPO₄ and an Al₂O₃—TiO₂ source can create the LATP layer. Certain exemplary embodiments can create columnar ceramic microstructures consisting of highly textured, single crystal columns (these structures are utilized as thermal barrier coatings for nickel based superalloy components in gas turbine engines). Following the bi-layer deposition, infiltration of a cyclo-olefin polymer or other non Li-ion conducting polymer into the columnar pores will occur. A subsequent light grit blast or etching step (to expose the LATP surface) and dissolving the water soluble NaCl layer can result in a free-standing separator.

Certain exemplary embodiments of UTPCC separator manufacture apply a lithium ion conducting composite onto a flexible substrate material followed by the eventual removal from the substrate prior to use. The lithium ion conducting composite can have properties to survive short term exposure to a high temperature, oxidative environment. Based on the properties of the ceramic materials (i.e. melting point) to be incorporated into the lithium ion conducting composite, a substrate temperature in the 300 to 700° C. range can be expected to create a desired columnar microstructure. Certain exemplary embodiments can utilize a thin, metal foil as the carrier material. Copper, stainless steel and/or nickel can provide high temperature capability and sufficient oxidation resistance (less so for copper) although other metals or alloys could be utilized. Such metals can be dissolved using acid solutions to provide a free standing UTPCC.

FIG. 1 shows A) a bi-layer LiPON/LATP deposition system and/or method 1100; a UTCPP Separator 1200 in transportable form and; a UTCPP Separator 1300 in final form. UTCPP Separator 1200 comprises a cyclo-olefin polymer layer 1210, an LATP layer 1220, a LiPON layer 1230, and a metal foil layer 1240. UTCPP Separator 1300 comprises a cyclo-olefin polymer layer 1310, an LATP layer 1320, and a LiPON layer 1330.

FIG. 1 comprises:
ATV Technology 1000;
an atmosphere 1010;
a soft vacuum 1020;
a vacuum chamber wall 1030;
LiPON Deposition 1040;
a flexible substrate 1050;
LATP deposition 1110;
a vapor shield 1400;
3D Coating Technology 1600;
High Efficiency Deposition Technology 1700;
Multi-source Evaporation Technology 1800;
a first Al₂O₃/TiO₂ source 1810;
a first LiPO₄ source 1820;
a second Al₂O₃/TiO₂ source 1830;
a second LiPO₄ source 1840;
Ar carrier gas 1850;
a first nozzle 1860;
a third LiPO₄ source 1500;
Ar+N₂ carrier gas 1510;
a second nozzle 1520;
a cathode/anode 1900; and
a magnetically enhanced hollow cathode plasma with rapidly switching cathode polarity 1910.

To meet a product cost target, the key techno-economic challenges are to obtain high deposition rates over large substrate areas using continuous, roll-to-roll manufacturing. Certain exemplary embodiments provide a unique vapor deposition process that combines relatively high evaporation rates (using electron beam vaporization), relatively high deposition efficiency (gas jet assist), relatively large area deposition (3D coating zone) and substantially continuous roll-to-roll manufacturing (ATV technology) to enable high deposition rates (greater than approximately 10 microns/minute) over large areas (greater than approximately one m²) in a substantially continuous manner. Certain exemplary processes for UTPCC separator manufacture allows for substantially continuous manufacturing of certain processing steps.

FIG. 3 is a schematic representation of a system 3000, in which elemental lithium metal is oxidized at an anode 3100 to form lithium ions 3020 and electrons 3040. Electrons 3040 flow through an electric circuit 3700 across a load 3800 to do electric work, and lithium ions 3020 migrate across an electrolyte 3500 to reduce oxygen (e.g., from air) at a cathode 3600.

An electrolyte 3500 can be utilized to transport lithium ions 3020 to anode 3100, and can comprise solid-state lithium ion conducting materials, organic electrolytes, and/or aqueous electrolytes. For example, in an organic electrolyte, gaseous oxygen is reduced to form lithium peroxide at cathode 3600, and in aqueous solution reduction of gaseous oxygen to lithium hydroxide occurs at cathode 3600. In certain exemplary embodiments, an ultra-thin polymer ceramic composite separator 3400 can be used to resist water contact with anode 3100, and ultra-thin polymer ceramic composite separator 3400 can be placed in close proximity to anode 3100. Ultra-thin polymer ceramic composite separator 3400 can comprise a first bi-layer 3200 and a second bi-layer 3300. If electrolyte 3500 is organic the system 3000, ultra-thin polymer ceramic composite separator 3400 can be useful to keep oxygen and any introduced water and CO₂ away from anode 3100. In certain exemplary embodiments, system 3000 can comprise a multi-electrolyte cell in which the electrolyte solutions in contact with anode 3100 and cathode 3600 are different.

Ultra-thin polymer ceramic composite separator 3400 can comprise a bi-layer of Li-ion conducting ceramic materials, the bi-layer comprising LiPON (e.g., first bi-layer 3200) and LATP (e.g., second bi-layer 3300), the bi-layer having a columnar grained microstructure. The columnar grained microstructure limits grain boundary resistance via alignment of boundaries in a direction of Li-ion transport.

Ultra-thin polymer ceramic composite separator 3400 can be constructed for use in system 3000 (e.g., which can comprise a battery). Ultra-thin polymer ceramic composite separator 3400 can have a thickness of less than 20 micrometers. Ultra-thin polymer ceramic composite separator 3400 can have a thickness of less than 10 micrometers.

Ultra-thin polymer ceramic composite separator 3400 can comprise a Li-ion conducting ceramic material. The Li-ion conducting ceramic material can have having a columnar grained microstructure.

Ultra-thin polymer ceramic composite separator 3400 can comprise a single or bi-layer combination of LiPON, LATP, garnets, lithium sulfides, or Li₁₊₂ₓZr_{2-z}Ca(PO₄)₃.

Ultra-thin polymer ceramic composite separator 3400 can comprise a single or bi-layer combination of a glass, materials having a NASICON structure, garnet, perovskite or sulfides having a thio-LISICON structure (for example, Li_{3.25}Ge_{0.25}P_{0.75} S₄ or LGPS).

When system 3000 comprises a battery, the battery can be:
a lithium ion battery;
a lithium sulfur battery;
a lithium air battery; and/or
a solid state battery.

Ultra-thin polymer ceramic composite separator 3400 can comprise:
a non Li-ion conducting polymer; and/or
a cyclo-olefin and an ion-conducting ceramic.

The columnar grained microstructure can limit grain boundary resistance by aligning grain boundaries in a direction of Li-ion transport.

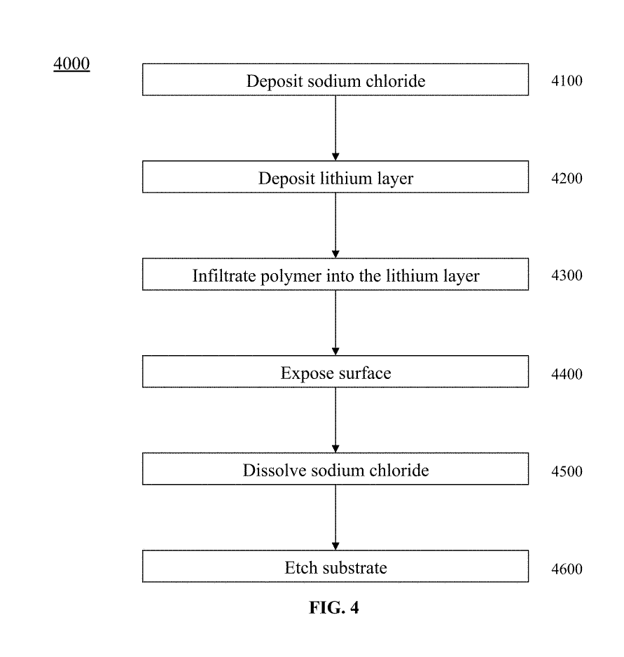

FIG. 4 is a flowchart of an exemplary embodiment of a method 4000. At activity 4100, a sodium chloride layer can be deposited. At activity 4200, a lithium layer can be deposited. For example, a lithium bi-layer can be deposited on a metal foil. The metal foil can have the sodium chloride layer deposited thereon. An initial LiPON layer can be deposited on the metal foil followed by an LATP layer. The bi-layer can be deposited via a gas-jet assisted vapor deposition process that operates in a soft vacuum of approximately 10 Pa. The bi-layer can be deposited via a gas-jet assisted vapor deposition process that utilizes non-line-of-sight coating.

The bi-layer can comprise LiPON and/or LATP, wherein:
the LiPON portion of the bi-layer is deposited via evaporation of a LiPO₄ source in a plasma enhanced, nitrogen rich environment; and/or
the LATP portion of the bi-layer is deposited via co-evaporation of LiPO₄ and Al₂O₃—TiO₂.

At activity 4300, a polymer can be infiltrated into the lithium layer. For example, a Li-ion conducting polymer can be infiltrated into the bi-layer. A non Li-ion conducting polymer can be infiltrated into columnar pores of the bi-layer.

At activity 4400, a surface of the lithium layer can be exposed. For example, the bi-layer can be etched to expose an LATP surface. In other embodiments, the bi-layer can be grit blasted to expose an LATP surface

At activity 4500, the sodium chloride layer can be dissolved. At activity 4600, a substrate comprising the lithium layer can be etched to leave a free-standing ultra-thin polymer ceramic composite separator.

The bi-layer can comprise columnar ceramic microstructures, the columnar ceramic microstructures comprising single crystal columns. The bi-layer can be deposited via a substantially continuous process.

### Definitions

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.

a—at least one.

activity—an action, act, step, and/or process or portion thereof.

adapter—a device used to effect operative compatibility between different parts of one or more pieces of an apparatus or system.

align—to be arranged in substantially a straight line.

and/or—either in conjunction with or in alternative to.

apparatus—an appliance or device for a particular purpose

associate—to join, connect together, and/or relate.

battery—one or more electrochemical cells adapted to convert stored chemical energy into electrical energy.

bi-layer—a structure comprising two layers.

boundary—a border.

can—is capable of, in at least some embodiments.

circuit—an electrically conductive pathway and/or a communications connection established across two or more switching devices comprised by a network and between corresponding end systems connected to, but not comprised by the network.

columnar grained—having a structure that comprises crystals grown in a substantially regular manner when a vertical section is viewed.

columnar pores—apertures defined in a columnar grained microstructure.

comprising—including but not limited to.

configure—to make suitable or fit for a specific use or situation.

connect—to join or fasten together.

constructed to—made to and/or designed to.

continuous process—a flow production method used to manufacture, produce, or process materials substantially without interruption.

convert—to transform, adapt, and/or change.

coupleable—capable of being joined, connected, and/or linked together.

coupling—linking in some fashion.

crystal column—a row of solid grains of a substance having a characteristic internal structure and enclosed by symmetrically arranged plane surfaces, intersecting at definite and characteristic angles.

cyclo-olefin—any of a homologous series of unsaturated, alicyclic hydrocarbons, as cyclooctatetraene and cyclopentadiene, containing one double bond in the ring and having the general formula C₁₁H₂ₙ₋₂.

define—to establish the outline, form, or structure of.

deposit—to place something on a surface.

determine—to obtain, calculate, decide, deduce, and/or ascertain.

device—a machine, manufacture, and/or collection thereof.

direction—a line along which something moves.

dissolve—to mix with a liquid and become part of the liquid.

etch—to cut into something via a substance such as an acid.

evaporate—to change from a liquid or solid state into a vapor state.

expose—to remove a material from a covered surface.

garnet—any of several red, brown, black, green, or yellow minerals having the general chemical formula A₃B₂SiO₈, where A is either calcium (Ca), magnesium (Mg), iron (Fe), or manganese (Mn) and B is either aluminum (Al), manganese, iron, chromium (Cr), or vanadium (V). Garnet crystals are dodecahedral in shape, transparent to semitransparent, and have a vitreous luster. A garnet can be an LLZO garnet and/or can comprise Li₇La₃Zr₂O₁₂.

gas turbine engine—a type of internal combustion engine that has an upstream rotating compressor coupled to a downstream turbine, and a combustion chamber or area, called a combustor, in between.

gas-jet assisted vapor deposition process—a method of coating a material that utilizes conveyance of a coating material via a stream of a substance in a gaseous state.

generate—to create, produce, give rise to, and/or bring into existence.

glass—a substantially noncrystalline substance (e.g., comprising LiPON).

grain boundary resistance—an impedance to electrical conductivity caused by crystalline borders in a microstructure.

grit blast—to change a surface via particulates entrained in a gas stream.

infiltrate—to undergo or cause to undergo the process in which a fluid passes into the pores or interstices of a solid.

install—to connect or set in position and prepare for use.

ion conducting ceramic—a substance that comprises a material such as, for example, silicon carbide, alumina, silicon carbide, zirconium oxide, and/or fused silica, calcium sulfate, luminescent optical ceramics, bio-ceramics, and/or plaster, etc. that is capable of transporting ions between a battery anode and cathode.

LATP—Li₁₊ₓAlₓTi₂₋ₓP₃O₁₂.

layer—a quantity of material placed on the surface of something.

LCZP—Li₁₊₂ₓZr_{2-z}Ca(PO₄)₃.

Li-ion conducting ceramic material—a substance that comprises a material such as, for example, silicon carbide, alumina, silicon carbide, zirconium oxide, and/or fused silica, calcium sulfate, luminescent optical ceramics, bio-ceramics, and/or plaster, etc. that is capable of transporting lithium ions between a battery anode and cathode.

Li-ion conducting polymer—a large molecule, or macromolecule, composed of many repeated subunits that is capable of transporting lithium ions between a battery anode and cathode.

Li-ion transport—movement of lithium ions between a battery anode and cathode.

limit—to restrict something.

LiPON—lithium phosphorous oxy-nitride.

lithium sulfide—a substance that comprises a compound of lithium and sulfur with a more electropositive element or group of elements.

may—is allowed and/or permitted to, in at least some embodiments.

metal foil—a thin sheet of a material, the material is typically hard, opaque, shiny, and has good electrical and thermal conductivity. Metals are generally malleable—that is, they can be hammered or pressed permanently out of shape without breaking or cracking—as well as fusible (able to be fused or melted) and ductile (able to be drawn out into a thin wire). About 91 of the 118 elements in the periodic table are metals.

method—a process, procedure, and/or collection of related activities for accomplishing something.

microstructure—the structure of a prepared surface of material as revealed by a microscope above approximately 25× magnification.

NASICON structure—NASICON is an acronym for sodium (Na) Super Ionic Conductor, which refers to a family of solids with the chemical formula Na₁+xZr₂SixP₃−xO₁₂, 0<x<3. A NASICON structure describes similar compounds where Na, Zr and/or Si are replaced by isovalent elements. NASICON compounds have high ionic conductivities, on the order of 10-3 S/cm, which rival those of liquid electrolytes. Substances having a NASICON structure can comprise, for example, Li₁+yAl_{y}Ti₂−y(PO₄)₃ and/or LATP.

nitrogen rich environment—having a nitrogen concentration that is greater than a nitrogen content of air (i.e., a nitrogen content greater than 79%).

non-line-of-site coating—placing a material on portions of something that are not visible to a human via observation from a fixed point in space from which the material enters a coating system.

particle diameter—an distance across a greatest extent of a particle.

perovskite—any material with the same type of crystal structure as calcium titanium oxide (CaTiO₃), known as the perovskite structure, or ^{XII}A^{2+VI}B⁴⁺X²⁻₃ with the oxygen in the face centers (such as, for example, La_{0.51}Li_{0.34}TiO_{2.94}).

plasma—one of four main states of matter, similar to a gas, but consisting of positively charged ions with most or all of their detached electrons moving freely about.

plasma enhanced—energized via a plasma generator.

plasma flux—a flow of plasma from a plasma source.

plasma generator—a system constructed to impart energy to a coating material and thereby generate a plasma.

plurality—the state of being plural and/or more than one.

predetermined—established in advance.

provide—to furnish, supply, give, and/or make available.

receive—to get as a signal, take, acquire, and/or obtain.

repeatedly—again and again; repetitively.

request—to express a desire for and/or ask for.

set—a related plurality.

single—substantially one.

substantially—to a great extent or degree.

superalloy—a mixture comprising a metal that exhibits: excellent mechanical strength, resistance to thermal creep deformation, good surface stability, and resistance to corrosion or oxidation.

support—to bear the weight of, especially from below.

system—a collection of mechanisms, devices, machines, articles of manufacture, processes, data, and/or instructions, the collection designed to perform one or more specific functions.

thermal barrier coating—a surface covering that provides insulation from heat transfer.

thickness—a distance measured between opposing surfaces of something.

thio-LISICON structure—LISICON is an acronym for Lithium Super Ionic Conductor, which refers to a family of solids with a chemical formula Li₂₊₂ₓZn₁₋ₓGeO₄. A NASICON structure describes similar compounds. For example, Li_{3.25}Ge_{0.25}P_{0.75}S₄ or LGPS have a thio-LISICON structure.

ultra-thin polymer ceramic composite separator—a layered structure that is less than approximately 20 micrometers thick and positioned adjacent to a lithium battery anode.

utilize—to use something for a particular purpose.

via—by way of and/or utilizing.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.

Thus, regardless of the content of any portion (e.g., title, field, background, summary, description, abstract, drawing figure, etc.) of this application, unless clearly specified to the contrary, such as via explicit definition, assertion, or argument, with respect to any claim, whether of this application and/or any claim of any application claiming priority hereto, and whether originally presented or otherwise:

there is no requirement for the inclusion of any particular described or illustrated characteristic, function, activity, or element, any particular sequence of activities, or any particular interrelationship of elements;

no characteristic, function, activity, or element is “essential”;

any elements can be integrated, segregated, and/or duplicated;

any activity can be repeated, any activity can be performed by multiple entities, and/or any activity can be performed in multiple jurisdictions; and

any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing figure, etc.) of this application, other than the claims themselves, is to be regarded as illustrative in nature, and not as restrictive, and the scope of subject matter protected by any patent that issues based on this application is defined only by the claims of that patent.

What is claimed is:

1. A system comprising:
an ultra-thin polymer ceramic composite separator, the ultra-thin polymer ceramic composite separator comprising a bi-layer of Li-ion conducting ceramic materials, the bi-layer comprising LiPON and LATP, the bi-layer having a columnar grained microstructure.

2. The system of claim 1, wherein:
the columnar grained microstructure limits grain boundary resistance via alignment of boundaries in a direction of Li-ion transport.

3. The system of claim 1, wherein:
the ultra-thin polymer ceramic composite separator is constructed for use in a battery.

4. The system of claim 1, wherein:
the ultra-thin polymer ceramic composite separator has a thickness of less than 20 micrometers.

5. The system of claim 1, wherein:
the ultra-thin polymer ceramic composite separator has a thickness of less than 10 micrometers.

6. A system comprising:
a battery comprising an ultra-thin polymer ceramic composite separator, the ultra-thin polymer ceramic composite separator comprising a Li-ion conducting ceramic material, the Li-ion conducting ceramic material having a columnar grained microstructure.

7. The system of claim 6, wherein:
the ultra-thin polymer ceramic composite separator comprises a single or bi-layer combination of LiPON, LATP, garnets, lithium sulfides, or Li₁₊₂ₓZr_{2-z}Ca(PO₄)₃.

8. The system of claim 6, wherein:
the ultra-thin polymer ceramic composite separator comprises a single or bi-layer combination of a glass, materials having a NASICON structure, garnet, perovskite or sulfides having a thio-LISICON structure.

9. The system of claim 6, wherein:
the battery is a lithium ion battery.

10. The system of claim 6, wherein:
the battery is a lithium sulfur battery.

11. The system of claim 6, wherein:
the battery is a lithium air battery.

12. The system of claim 6, wherein:
the battery is a solid state battery.

13. The system of claim 6, wherein:
the ultra-thin polymer ceramic composite separator has a thickness of less than 20 micrometers.

14. The system of claim 6, wherein:
the ultra-thin polymer ceramic composite separator comprises a non Li-ion conducting polymer.

15. The system of claim 6, wherein:
the ultra-thin polymer ceramic composite separator comprises a cyclo-olefin and an ion-conducting ceramic.

16. The system of claim 6, wherein:
the columnar grained microstructure limits grain boundary resistance by aligning grain boundaries in a direction of Li-ion transport.

17. A method comprising:
depositing a bi-layer on a metal foil, the metal foil having deposited sodium chloride thereon, the bi-layer comprising a LiPON and LATP, wherein:
the LiPON portion of the bi-layer is deposited via evaporation of a LiPO₄ source in a plasma enhanced, nitrogen rich environment; and
the LATP portion of the bi-layer is deposited via co-evaporation of LiPO₄ and Al₂O₃—TiO₂.

18. The method of claim 17, further comprising:
infiltrating a Li-ion conducting polymer into the bi-layer.

19. The method of claim 17, further comprising:
infiltrating a non Li-ion conducting polymer into columnar pores of the bi-layer.

20. The method of claim 17, further comprising:
etching the bi-layer to expose an LATP surface.

21. The method of claim 17, further comprising:
grit blasting the bi-layer to expose an LATP surface.

22. The method of claim 17, further comprising:
dissolving the deposited sodium chloride.

23. The method of claim 17, further comprising:
etching away a substrate comprising the bi-layer to leave a free-standing ultra-thin polymer ceramic composite separator.

24. The method of claim 17, wherein:
the bi-layer comprises columnar ceramic microstructures, the columnar ceramic microstructures comprising single crystal columns.

25. The method of claim 17, wherein:
the bi-layer is deposited via a substantially continuous process.

26. The method of claim 17, wherein:
an initial LiPON layer is deposited on the metal foil followed by an LATP layer.

27. The method of claim 17, wherein:
the bi-layer is deposited via a gas-jet assisted vapor deposition process that operates in a soft vacuum of approximately 10 Pa.

28. The method of claim 17, wherein:
the bi-layer is deposited via a gas-jet assisted vapor deposition process that utilizes non-line-of-sight coating.
